(19) United States
(12) Patent Application Publication
(10) Pub. No.: US 2017/0033801 A1
(43) Pub. Date: Feb. 2, 2017

(54) METHOD AND APPARATUS FOR EXCESS LOOP DELAY COMPENSATION IN DELTA-SIGMA MODULATOR

(71) Applicants: Chi-Lun LO, Yangmei City, Taoyuan County (TW); Stacy HO, Reading, MA (US); MediaTek Singapore Pte. Ltd., Singapore (SG)

(72) Inventors: Chi-Lun Lo, Taoyuan City (TW); Stacy Ho, Reading, MA (US)

(73) Assignee: Mediatek Singapore PTE. LTD., Singapore (SG)

(21) Appl. No.: 15/112,691

(22) PCT Filed: Jan. 20, 2015
(86) PCT No.: PCT/US2015/012098

§ 371 Date: Jul. 20, 2016

Related U.S. Application Data
(60) Provisional application No. 61/929,688, filed on Jan. 21, 2014.

(51) Int. Cl. H03M 3/00

(52) U.S. Cl. CPC H03M 3/422; H03M 3/50; H03M 3/37

(57) ABSTRACT

A delta-sigma modulator includes a signal subtraction circuit, a loop filter, a quantizer, a digital-to-analog converter (DAC), and a control circuit. The signal subtraction circuit subtracts an analog feedback signal from an analog input signal to generate a difference signal. The loop filter performs a filtering operation upon the difference signal to generate a filtered signal. The quantizer quantizes the filtered signal into a digital out put signal, wherein at least one inherent circuit characteristic of the quantizer are adjusted in response to a digital code input. The DAC generates the analog feedback signal according to the digital output signal. The control circuit generates the digital code input to the quantizer for setting an excess loop delay (ELD) compensation.

### CROSS REFERENCE TO RELATED APPLICATIONS

This application claims the benefit of U.S. provisional application No. 61/929,688, filed on Jan. 21, 2014 and incorporated herein by reference.

### BACKGROUND

The disclosed embodiments of the present invention relate to converting an analog signal into a digital signal, and more particularly, to a method and apparatus for excess loop delay compensation in a delta-sigma modulator.

Analog techniques have dominated signal processing for years, but digital techniques are encroaching into this domain. An analog-to-digital converter is needed to convert an analog signal into a digital signal, thus allowing the signal to be processed in a digital domain. For example, a delta-sigma analog-to-digital converter (ΔΣ ADC) may be used for converting analog signals over a wide range of frequencies. In general, a core part of the delta-sigma analog-to-digital converter is a delta-sigma modulator which is responsible for digitizing/quantizing the analog input signal and reducing noise at lower frequencies. In this stage, the architecture implements a function called noise shaping that pushes low-frequency noise (e.g., quantization noise) up to higher frequencies outside the in-band (i.e., the band of interest). Noise shaping is one of the reasons that the delta-sigma modulators are well-suited for low-frequency, higher-accuracy applications.

It is well known that a continuous-time delta-sigma modulator requires a means to compensate for signal delay in the delta-sigma modulation loop that is introduced by quantizer delay, digital-to-analog converter (DAC) switching delays, and finite gain-bandwidth of integrators in the loop filter. If the timing errors are continuously accumulated at integrators within the loop filter through the feedback DAC, the overall performance of the continuous-time delta-sigma modulator degrades. There are several widely used methods for accomplishing this compensation task, and these methods are collectively referred to as “excess loop delay (ELD) compensation”. However, the conventional digital ELD compensation methods are not suitable for delta-sigma modulators under high clock rates. For example, when the clock rate exceeds 2 GHz, the amount of power required to satisfy the operational constraints would severely limit the practicality of the conventional digital ELD compensation method.

### SUMMARY

In accordance with exemplary embodiments of the present invention, a method and apparatus for excess loop delay compensation in a delta-sigma modulator are proposed.

According to a first aspect of the present invention, an exemplary delta-sigma modulator is disclosed. The exemplary delta-sigma modulator includes a signal subtraction circuit, a loop filter, a quantizer, a digital-to-analog converter (DAC), and a control circuit. The signal subtraction circuit is arranged to subtract an analog feedback signal from an analog input signal to generate a difference signal. The loop filter is arranged to perform a filtering operation upon the difference signal to generate a filtered signal. The quantizer is arranged to quantize the filtered signal into a digital output signal, wherein at least one inherent circuit characteristic of the quantizer is adjusted in response to a digital code input. The DAC is arranged to generate the analog feedback signal according to the digital output signal. The control circuit is arranged to generate the digital code input to the quantizer for setting an excess loop delay (ELD) compensation.

According to a second aspect of the present invention, an exemplary analog-to-digital conversion circuit is disclosed. The exemplary analog-to-digital conversion circuit includes a quantizer and a control circuit. The quantizer is arranged to quantize an analog signal into a digital signal, and comprises a plurality of comparators, each receiving the analog signal and having a digitally controlled comparator offset acting as a threshold level that is compared with the analog signal. The control circuit has a plurality of multiplexers, coupled to the comparators, respectively, wherein each of the multiplexers is arranged to receive a plurality of candidate digital codes and output one of the candidate digital codes to a corresponding comparator, and digitally controlled comparator offsets of the comparators are set by digital codes generated from the multiplexers, respectively.

According to a third aspect of the present invention, an exemplary delta-sigma modulation method is disclosed. The exemplary delta-sigma modulation method includes: subtracting an analog feedback signal from an analog input signal to generate a difference signal; performing a filtering operation upon the difference signal to generate a filtered signal; generating a digital code input to a quantizer for setting an excess loop delay (ELD) compensation; adjusting at least one inherent circuit characteristic of the quantizer according to the digital code input; utilizing the quantizer to quantize the filtered signal into a digital output signal; and performing a digital-to-analog conversion operation based on the digital output signal and accordingly generating the analog feedback signal.

According to a fourth aspect of the present invention, an exemplary analog-to-digital conversion method is disclosed. The exemplary analog-to-digital conversion method includes: utilizing a quantizer to quantize an analog signal into a digital signal, wherein the quantizer comprises a plurality of comparators, each receiving the analog signal and having a digitally controlled comparator offset acting as a threshold level that is compared with the analog signal; and generating a plurality of digital codes to the comparators, respectively, wherein each of the digital codes is generated by receiving a plurality of candidate digital codes, and selecting one of the candidate digital codes as a digital code transmitted to a corresponding comparator; and setting digitally controlled comparator offsets of the comparators according to the digital codes, respectively.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 is a block diagram illustrating a delta-sigma modulator using a proposed excess loop delay compensation scheme according to an embodiment of the present invention.

FIG. 2 is a diagram illustrating an exemplary embodiment of the analog-to-digital conversion circuit shown in FIG. 1.

FIG. 3 is a circuit diagram of a dynamic comparator using two methods to set a comparator offset.

FIG. 4 is a diagram illustrating exemplary comparator offsets controlled by digital code groups when a coefficient is set by one value.

FIG. 5 is a diagram illustrating exemplary comparator offsets controlled by digital code groups when a coefficient is set by another value.

FIG. 6 is a diagram illustrating exemplary comparator offsets controlled by digital code groups when a coefficient is set by yet another value.

### DETAILED DESCRIPTION

Certain terms are used throughout the description and following claims to refer to particular components. As one skilled in the art will appreciate, manufacturers may refer to a component by different names. This document does not intend to distinguish between components that differ in name but not function. In the following description and in the claims, the terms “include” and “comprise” are used in an open-ended fashion, and thus should be interpreted to mean “include, but not limited to . . . ”. Also, the term “couple” is intended to mean either an indirect or direct electrical connection. Accordingly, if one device is coupled to another device, that connection may be through a direct electrical connection, or through an indirect electrical connection via other devices and connections.

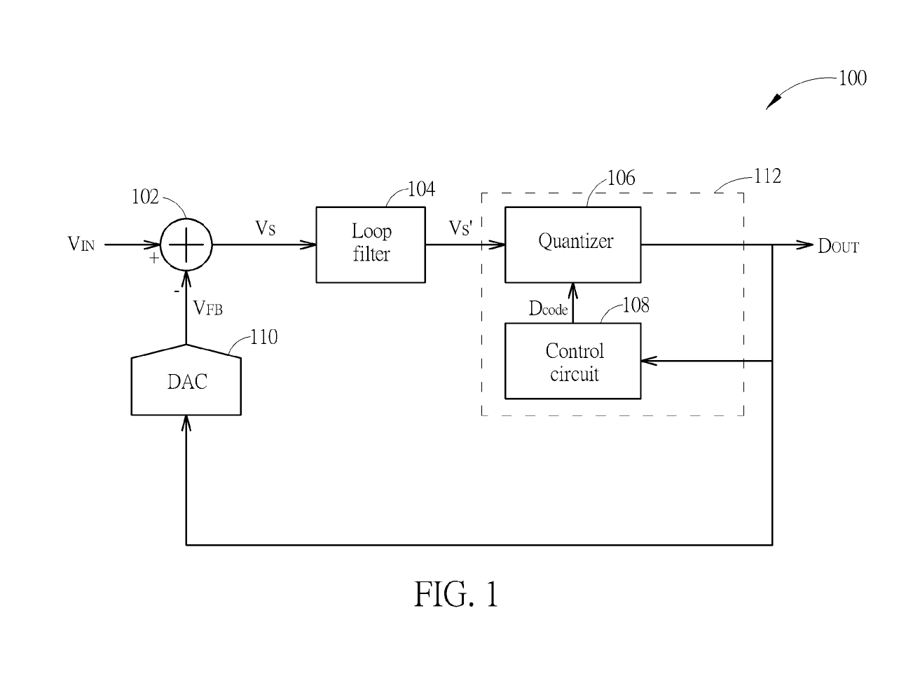

FIG. 1 is a block diagram illustrating a delta-sigma modulator using a proposed excess loop delay (ELD) compensation scheme according to an embodiment of the present invention. The delta-sigma modulator 100 is a continuous-time delta-sigma modulator, and includes a signal subtraction circuit 102, a loop filter 104, a quantizer 106, a control circuit 108, and a digital-to-analog converter (DAC) 110. The signal subtraction circuit 102 may be an adder (which may be implemented using a difference amplifier to perform analog signal subtraction). The signal subtraction circuit 102 is arranged to subtract an analog feedback signal V_{FB} from an analog input signal VIN to generate a difference signal V_{S}. The loop filter 104 may include one or more integrators/resonators. The loop filter 104 is arranged to perform a filtering operation upon the difference signal Vs to generate a filtered signal V_{S}′. The combination of quantizer 106 and control circuit 108 may be regarded as an analog-to-digital conversion circuit 112 with an ELD compensation function integrated therein. The quantizer 106 is controlled by the control circuit 108, and arranged to quantize (i.e., digitize) the filtered signal Vs' into a digital output signal D_{OUT}. In this embodiment, the ELD compensation is performed with a scaling factor (or called “coefficient” a) at the quantizer 106 under the control of the control circuit 108. The DAC 110 is located in a feedback path between an output of the quantizer 106 and one input of the signal subtraction circuit 102, and arranged to perform a digital-to-analog conversion operation based on the digital output signal D_{OUT} and accordingly generate the analog feedback signal V_{FB} to the signal subtraction circuit 102. The signal subtraction circuit 102, loop filter 104 and DAC 110 may be implemented using conventional designs. As the present invention focuses on the design of the analog-to-digital conversion circuit 112, further description of signal subtraction circuit 102, loop filter 104 and DAC 110 is omitted here for brevity.

In this embodiment, the control circuit 108 is arranged to generate a digital code input D_{code} to the quantizer 106 for setting the ELD compensation, where at least one inherent circuit characteristic of the quantizer 106 is adjusted in response to the digital code input D_{code}. In one exemplary implementation, the at least one inherent circuit characteristic of the quantizer 106 is adjusted by changing a hardware configuration of the quantizer 106. For example, the at least one inherent circuit characteristic of the quantizer 106 includes a threshold level setting inherent to the quantizer 106, such that the ELD compensation is effectively achieved by an analog subtraction at an input of the quantizer 106. It should be noted that the threshold levels (i.e., quantization levels) are created inside the quantizer 106 rather than provided from an external circuit of the quantizer 106.

The control circuit 108 controls and adjusts the ELD compensation applied to the delta-sigma modulator 100 in a digital manner. It should be noted that the control circuit 108 generates the digital code input D_{code} to the quantizer 106 instead of directly providing the threshold levels (i.e., quantization levels) to the quantizer 106. Hence, using a multiplexer for selecting threshold voltages from a plurality of candidate threshold voltages generated by a resistor string is avoided. The conventional digital ELD compensation method is only useful if the coefficient α can be made or rounded to a value that is easily implemented without multipliers, i.e., the coefficient α must be a power-of-two value 2^{N}. Since the control circuit 108 can generate the digital code input D_{code} to easily adjust the threshold level setting inherent to the quantizer 106 (i.e., ELD compensation performed at the quantizer 106), the coefficient α is not constrained to be a power-of-two value 2^{N}. Further, the control circuit 108 does not have active and passive components located in a signal path of the delta-sigma modulation loop, such that there is no signal delay (e.g., gate delay) introduced by the control circuit 108. To put it simply, the proposed digital ELD compensation scheme of the present invention overcomes the limitations in the conventional digital ELD compensation schemes and is practical beyond a high clock rate such as 2 GHz.

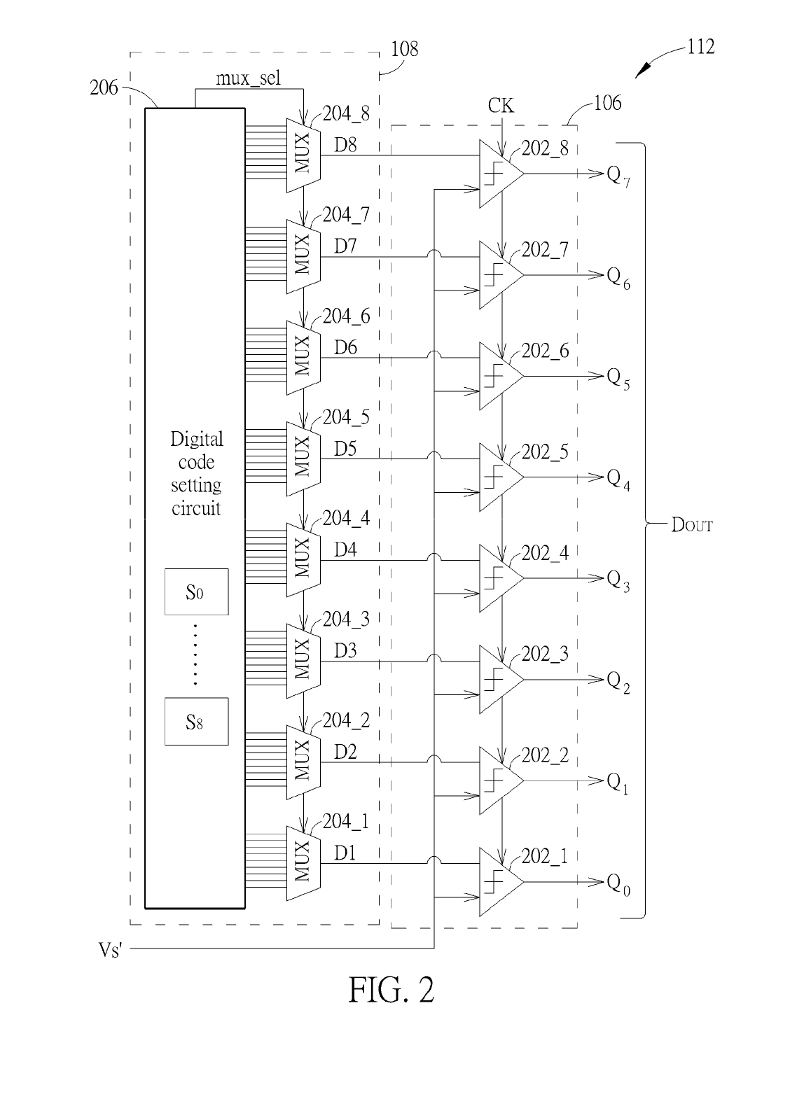

FIG. 2 is a diagram illustrating an exemplary embodiment of the analog-to-digital conversion circuit 112 shown in FIG. 1. The quantizer 106 includes a plurality of comparators for generating a plurality of comparison results to serve as different bits of one digital value. In this embodiment, the quantizer 106 is shown having eight comparators 202_1-202_8. Hence, each digital value of the digital output signal Dour has eight bits Q₀-Q₇ generated from the comparators 202_1-202_8. By way of example, the comparators 202_1-202_8 may be implemented using dynamic comparators (or called “clocked comparators”), each receiving the same filtered signal Vs' (i.e., loop filter output) and having a digitally controlled comparator offset acting as a threshold level that is compared with the filtered signal V_{S}′. In addition, the digital code input D_{code} has a plurality of digital codes. Since the number of comparators 202_1-202_8 implemented in the quantizer 106 is equal to 8, the control circuit 108 therefore generates eight digital codes D₁-D₈ to the comparators 202_1-202_8, respectively. In this way, the digitally controlled comparator offsets of the comparators 202_1-202_8 are controlled by the digital codes D₁-D₈, respectively.

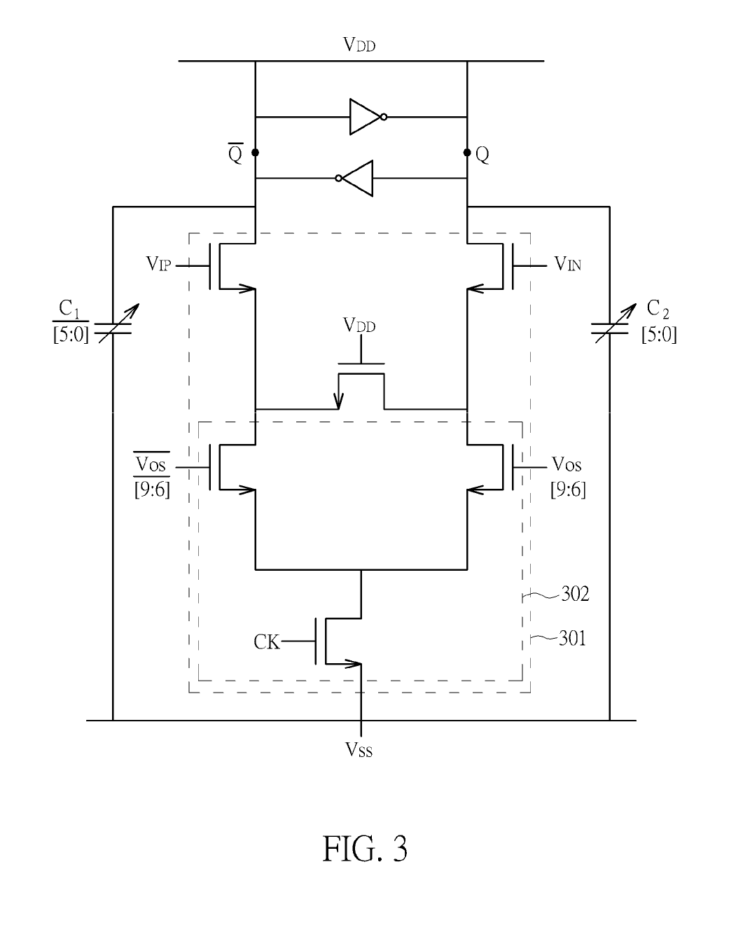

FIG. 3 is a circuit diagram of a dynamic comparator using two methods to set a comparator offset. By way of example, each of the comparators 202_1-202_8 may be implemented using the dynamic comparator 300 shown in FIG. 3. One method for setting the comparator offset is to create an imbalanced input pair, as shown in the dashed rectangle 301. For example, a binary-weighted tail-steering array, shown in the dashed rectangle 302, is controlled by 4 more significant bits [9:6] of a 10-bit digital code for coarse offset tuning. The other method for setting the comparator offset is to add imbalanced capacitor load, as shown by tunable capacitors C1 and C2. Each of the tunable capacitors C1 and C2 may be implemented using a capacitor array. Hence, the tunable capacitors C1 and C2 are controlled by 6 less significant bits [5:0] of the 10-bit digital code for fine offset tuning. However, this is for illustrative purposes only, and is not meant to be a limitation of the present invention. There are other methods that can be adopted to create an imbalanced structure in response to a digital code to thereby introduce the desired comparator offset that acts as one threshold level for signal quantization/digitization.

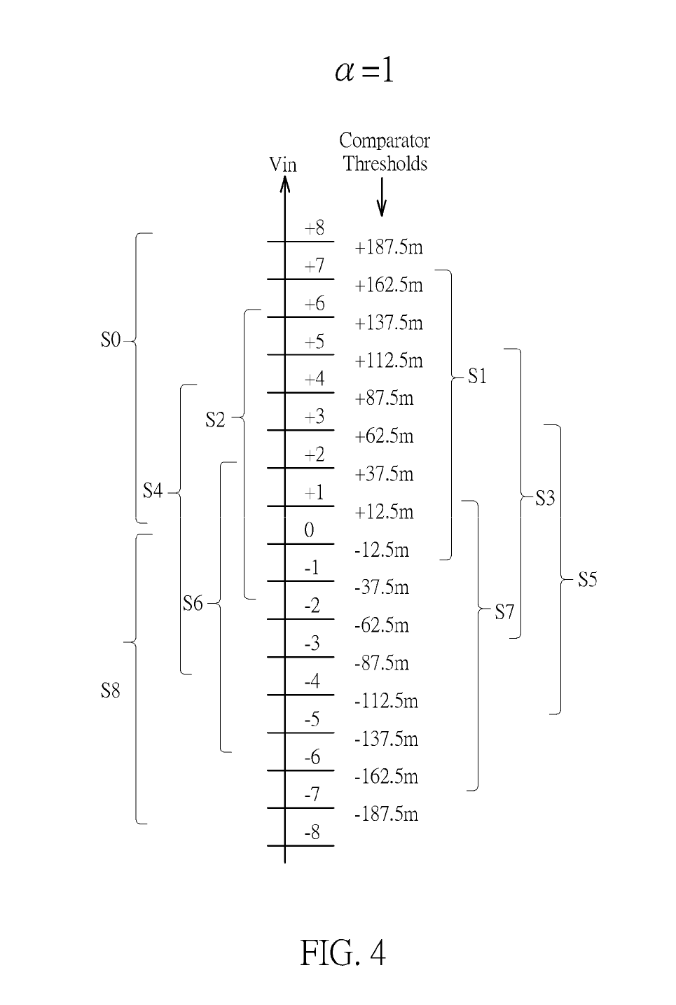

Please refer to FIG. 2 again. The control circuit 108 includes a plurality of multiplexers (MUXs) 204_1-204_8 and a digital code setting circuit 206. During a power-on period of an electronic device using the delta-sigma modulator 100, the digital code setting circuit 206 may calibrate nine digital code groups S₀-S₈ corresponding to the coefficient α used in the delta-sigma modulator 100, especially the ELD compensation performed within the analog-to-digital conversion circuit 112. FIG. 4 is a diagram illustrating exemplary comparator offsets controlled by the digital code groups S₀-S₈ when α=1. Each of the digital code groups S₀-S₈ may include eight digital codes, and each of the digital codes may have ten bits. After the calibration procedure is accomplished, each of the digital codes is ensured to make a comparator have a desired comparator offset if the digital code is selected and transmitted to the comparator. Taking the digital code group So for example, the 8^{th} digital code is used to set a largest comparator offset by +187.5 mV, the 7^{th} digital code is used to set a comparator offset by +162.5 mV, the 6^{th} digital code is used to set a comparator offset by +137.5 mV, the 5^{th} digital code is used to set a comparator offset by +112.5 mV, the 4th digital code is used to set a comparator offset by +87.5 mV, the 3^{rd} digital code is used to set a comparator offset by +62.5 mV, the 2^{nd} digital code is used to set a comparator offset by +37.5 mV, and the 1^{st} digital code is used to set a smallest comparator offset by +12.5 mV.

With regard to each of the digital code groups S₀-S₈, the digital code setting circuit 206 outputs digital codes of the same digital code group to different multiplexers 204_1-204_8 according to the order of corresponding comparator offsets. Taking the digital code group So for example, the 1^{st} digital code (which is used to set the smallest comparator offset) is received by the multiplexer 204_1, the 2^{nd} digital code is received by the multiplexer 204_2, the 3^{rd} digital code is received by the multiplexer 204_3, the 4^{th} digital code is received by the multiplexer 204_4, the 5^{th} digital code is received by the multiplexer 204_5, the 6^{th} digital code is received by the multiplexer 204_6, the 7^{th} digital code is received by the multiplexer 204_7, and the 8^{th} digital code (which is used to set the largest comparator offset) is received by the multiplexer 2048. In this way, each of the multiplexers 204_1-204_8 receives a plurality of candidate digital codes from different digital code groups, and outputs one of the candidate digital codes to a corresponding comparator.

Different digital code groups S₀-S₈ correspond to different ELD compensation settings, respectively. Hence, based on each digital value generated from the quantizer 106, the digital code setting circuit 206 determines which digital code group should be used to apply an appropriate ELD compensation to the delta-sigma modulation loop, and sets the multiplexer control signal mux_sel correspondingly. For example, when the digital code group So is selected by the multiplexer control signal mux_sel, the multiplexer 202_1 outputs the 1^{st} digital code of the digital code group So as the digital code D₁ such that the corresponding comparator 202_1 uses a built-in threshold level 12.5 mV that is digitally controlled by the digital code D₁, the multiplexer 202_2 outputs the 2^{nd} digital code of the digital code group So as the digital code D₂ such that the corresponding comparator 202_2 uses a built-in threshold level 37.5 mV that is digitally controlled by the digital code D₂, the multiplexer 202_3 outputs the 3^{rd} digital code of the digital code group So as the digital code D₃ such that the corresponding comparator 202_3 uses a built-in threshold level 62.5 mV that is digitally controlled by the digital code D₃, the multiplexer 202_4 outputs the 4^{th} digital code of the digital code group So as the digital code D₄ such that the corresponding comparator 202_4 uses a built-in threshold level 87.5 mV that is digitally controlled by the digital code D₄, the multiplexer 202_5 outputs the 5^{th} digital code of the digital code group So as the digital code D₅ such that the corresponding comparator 202_5 uses a built-in threshold level 112.5 mV that is digitally controlled by the digital code D₅, the multiplexer 202_6 outputs the 6^{th} digital code of the digital code group So as the digital code D₆ such that the corresponding comparator 202_6 uses a built-in threshold level 137.5 mV that is digitally controlled by the digital code D₆, the multiplexer 202_7 outputs the 7^{th} digital code of the digital code group So as the digital code D₇ such that the corresponding comparator 202_7 uses a built-in threshold level 162.5 mV that is digitally controlled by the digital code D₇, and the multiplexer 202_8 outputs the 8^{th} digital code of the digital code group So as the digital code D₈ such that the corresponding comparator 202_8 uses a built-in threshold level 187.5 mV that is digitally controlled by the digital code D₈.

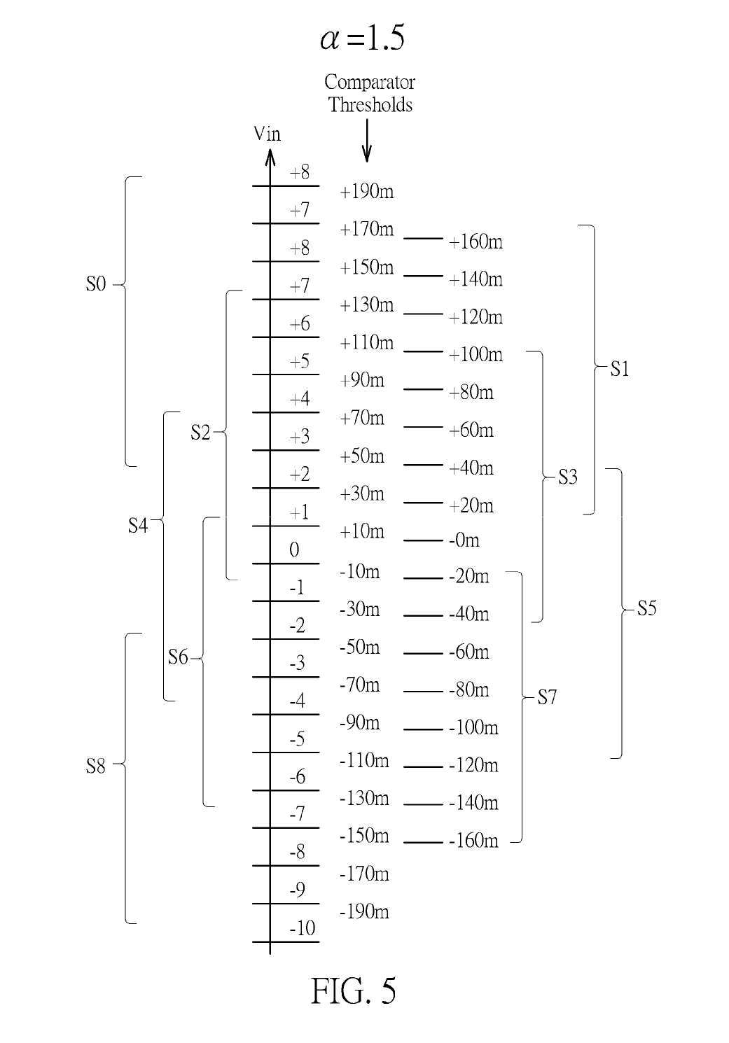

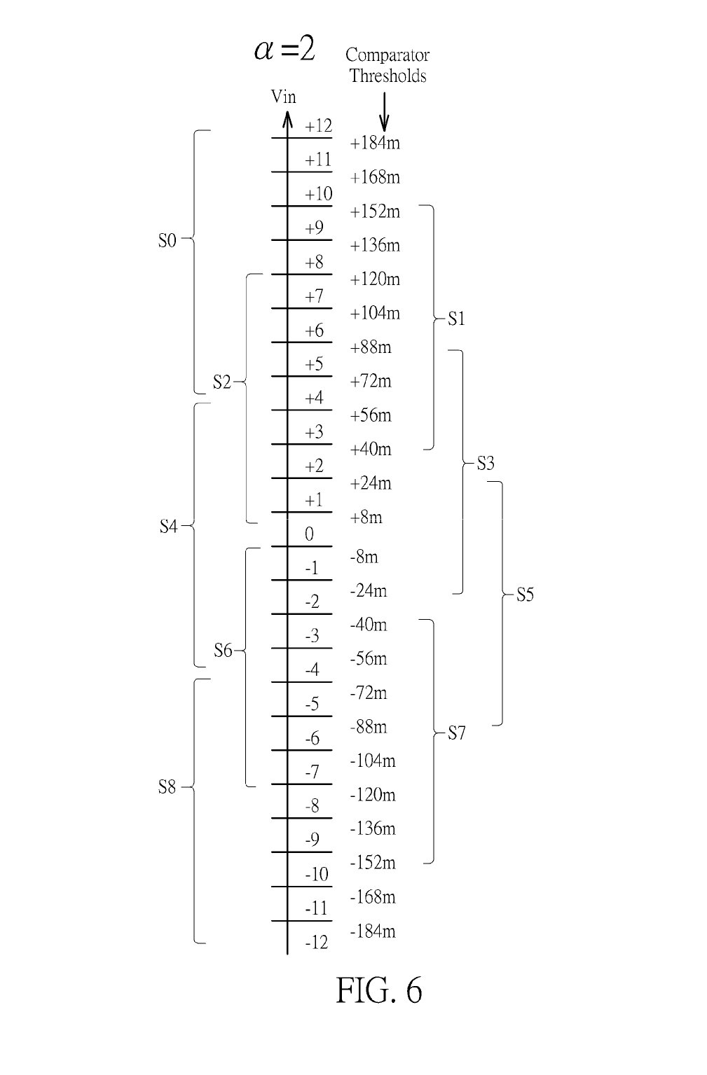

As mentioned above, during a power-on period of an electronic device using the delta-sigma modulator 1001 the digital code setting circuit 206 calibrates digital code groups S₀-S₈ corresponding to the coefficient α used in the delta-sigma modulator 100, especially the ELD compensation performed within the analog-to-digital conversion circuit 112. The digital code setting circuit 206 may be arranged to support calibration of digital code groups S₀-S₈ for different coefficient values, and adaptively adjusts digital codes in the digital code groups S₀-S₈. It should be noted that the coefficient α is allowed to have a value larger than one, and is not constrained to be a power-of-two value. FIG. 5 is a diagram illustrating exemplary comparator offsets controlled by the digital code groups S₀-S₈ when α=1.5. FIG. 6 is a diagram illustrating exemplary comparator offsets controlled by the digital code groups S₀-S₈ when α=2. In a case where the delta-sigma modulator 100 uses the coefficient α set by a first value (e.g., α=1 or 2), the digital code setting circuit 206 properly sets the digital code groups S₀-S₈ by first digital codes calibrated during a power-on period of an electronic device using the delta-sigma modulator 100. In another case where the delta-sigma modulator 100 uses the coefficient α set by a second value (e.g., α=1.5), the digital code setting circuit 206 properly sets the digital code groups S₀-S₈ by second digital codes calibrated during a power-on period of an electronic device using the delta-sigma modulator 100.

In the present invention, the analog-to-digital conversion circuit 112 shown in FIG. 2 is part of the delta-sigma modulator 100 shown in FIG. 1. However, this is for illustrative purposes only, and is not meant to be a limitation of the present invention. That is, the analog-to-digital conversion circuit 112 with the proposed circuit structure may be used in any application requiring an analog-to-digital conversion function. Hence, any analog-to-digital conversion circuit using the proposed circuit structure shown in FIG. 2 also falls within the scope of the present invention.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A delta-sigma modulator, comprising:
a signal subtraction circuit, arranged to subtract an analog feedback signal from an analog input signal to generate a difference signal;
a loop filter, arranged to perform a filtering operation upon the difference signal to generate a filtered signal;
a quantizer, arranged to quantize the filtered signal into a digital output signal, wherein at least one inherent circuit characteristic of the quantizer is adjusted in response to a digital code input;
a digital-to-analog converter (DAC), arranged to generate the analog feedback signal according to the digital output signal; and
a control circuit, arranged to generate the digital code input to the quantizer for setting an excess loop delay (ELD) compensation.

2. The delta-sigma modulator of claim 1, wherein the ELD compensation is achieved by an analog subtraction at an input of the quantizer.

3. The delta-sigma modulator of claim 1, wherein a hardware configuration of the quantizer is adjusted in response to the digital code input, thus adjusting the at least one inherent circuit characteristic of the quantizer.

4. The delta-sigma modulator of claim 1, wherein the at least one inherent circuit characteristic of the quantizer includes a threshold level setting inherent to the quantizer.

5. The delta-sigma modulator of claim 1, wherein the quantizer comprises a plurality of comparators, each receiving the filtered signal and having a digitally controlled comparator offset acting as a threshold level that is compared with the filtered signal;
the digital code input comprises a plurality of digital codes; and
digitally controlled comparator offsets of the comparators are set based on the digital codes, respectively.

6. The delta-sigma modulator of claim 5, wherein the control circuit comprises:
a plurality of multiplexers, coupled to the comparators, respectively, wherein each of the multiplexers is arranged to receive a plurality of candidate digital codes and output one of the candidate digital codes to a corresponding comparator.

7. The delta-sigma modulator of claim 6, wherein the ELD compensation is performed with a coefficient; and the control circuit further comprises:
a digital code setting circuit, arranged to adaptively adjust the candidate digital codes received by each of the multiplexers according to the coefficient.

8. The delta-sigma modulator of claim 7, wherein the coefficient is not constrained to a power-of-two value.

9. An analog-to-digital conversion circuit, comprising:
a quantizer, arranged to quantize an analog signal into a digital signal, wherein the quantizer comprises:
a plurality of comparators, each receiving the analog signal and having a digitally controlled comparator offset acting as a threshold level that is compared with the analog signal; and
a control circuit, comprising:
a plurality of multiplexers, coupled to the comparators, respectively, wherein each of the multiplexers is arranged to receive a plurality of candidate digital codes and output one of the candidate digital codes to a corresponding comparator, and digitally controlled comparator offsets of the comparators are set by digital codes generated from the multiplexers, respectively.

10. The analog-to-digital conversion circuit of claim 9, wherein the analog-to-digital conversion circuit is part of a delta-sigma modulator.

11. A delta-sigma modulation method, comprising:
subtracting an analog feedback signal from an analog input signal to generate a difference signal;
performing a filtering operation upon the difference signal to generate a filtered signal;
generating a digital code input to a quantizer for setting an excess loop delay (ELD) compensation;
adjusting at least one inherent circuit characteristic of the quantizer according to the digital code input;
utilizing the quantizer to quantize the filtered signal into a digital output signal; and
performing a digital-to-analog conversion operation based on the digital output signal, and accordingly generating the analog feedback signal.

12. The delta-sigma modulation method of claim 11, wherein the ELD compensation is achieved by an analog subtraction at an input of the quantizer.

13. The delta-sigma modulation method of claim 11, wherein adjusting the at least one inherent circuit characteristic of the quantizer comprises:
adjusting a hardware configuration of the quantizer in response to the digital code input.

14. The delta-sigma modulation method of claim 11, wherein the at least one inherent circuit characteristic of the quantizer includes a threshold level setting inherent to the quantizer.

15. The delta-sigma modulation method of claim 11, wherein the quantizer comprises a plurality of comparators, each receiving the filtered signal and having a digitally controlled comparator offset acting as a threshold level that is compared with the filtered signal;
the digital code input comprises a plurality of digital codes; and
adjusting the at least one inherent circuit characteristic of the quantizer according to the digital code input comprises:
setting digitally controlled comparator offsets of the comparators according to the digital codes, respectively.

16. The delta-sigma modulation method of claim 15, wherein each of the digital codes is generated by:
receiving a plurality of candidate digital codes; and
selecting one of the candidate digital codes as a digital code transmitted to a corresponding comparator.

17. The delta-sigma modulation method of claim 16, wherein the ELD compensation is performed with a coefficient; and the delta-sigma modulation method further comprises:
adaptively adjusting the candidate digital codes according to the coefficient.

18. The delta-sigma modulation method of claim 17, wherein the coefficient is not constrained to a power-of-two value.

19. An analog-to-digital conversion method, comprising:
utilizing a quantizer to quantize an analog signal into a digital signal, wherein the quantizer comprises:
a plurality of comparators, each receiving the analog signal and having a digitally controlled comparator offset acting as a threshold level that is compared with the analog signal; and
generating a plurality of digital codes to the comparators, respectively, wherein each of the digital codes is generated by:
receiving a plurality of candidate digital codes; and
selecting one of the candidate digital codes as a digital code transmitted to a corresponding comparator; and
setting digitally controlled comparator offsets of the comparators according to the digital codes, respectively.

20. The analog-to-digital conversion method of claim 19, wherein the analog-to-digital conversion method is employed by a delta-sigma modulator.
